(19) United States
(12) Patent Application Publication
(10) Pub. No.: US 2013/0000711 A1
(43) Pub. Date: Jan. 3, 2013

(54) PHOTOELECTRIC CONVERSION DEVICE

(75) Inventors: Yoshikazu YAMAOKA, Ogaki-shi (JP); Shigeo Yata, Ogaki-shi (JP); Azumi Umeda, Kishiwada-shi (JP); Daiji Kanematsu, Anpachi-gun (JP)

(73) Assignee: Sanyo Electric Co., Ltd., Moriguchi-shi (JP)

(21) Appl. No.: 13/616,502

(22) Filed: Sep. 14, 2012

Related U.S. Application Data
(63) Continuation of application No. PCT/JP2011/060035, filed on Apr. 25, 2011.

(30) Foreign Application Priority Data
Apr. 28, 2010 (JP) 2010-104454

(51) Int. Cl. H01L 31/076

(52) U.S. Cl. 136/255

(57) ABSTRACT

In order to increase the photoelectric conversion efficiency of a photoelectric conversion device, the photoelectric conversion device (200) is provided with a first intermediate layer (44), which is arranged between a p-type layer (42) and an i-type layer (46) and which has a lower refractive index than refractive indices of the p-type layer (42) or the i-type layer (46), and a second intermediate layer (48), which is arranged between an n-type layer (50) and the i-type layer (46) and which has a lower refractive index than refractive indices of the n-type layer (50) or the i-type layer (46).

### CROSS-REFERENCE TO RELATED APPLICATION

The present application is a continuation application of International Application No. PCT/JP2011/060035, filed Apr. 25, 2011, the entire contents of which are incorporated herein by reference and priority to which is hereby claimed. The PCT/JP2011/060035 application claimed the benefit of the date of the earlier filed Japanese Patent Application No. 2010-104454 filed Apr. 28, 2010, the entire content of which is incorporated herein by reference, and priority to which is hereby claimed.

### TECHNICAL FIELD

The present invention relates to a photoelectric conversion device, and particularly to a photoelectric conversion device having an intermediate layer.

### BACKGROUND ART

Solar cells are known in which polycrystalline silicon, microcrystalline silicon, or amorphous silicon is used. In particular, a photoelectric conversion device in which microcrystalline or amorphous silicon thin films are layered has attracted much attention in view of resource consumption, reduction of cost, and improvement in efficiency.

In general, a photoelectric conversion device is formed by sequentially layering a first electrode, one or more semiconductor thin film photoelectric conversion units, and a second electrode over a substrate having an insulating surface. Each photoelectric conversion unit is formed by layering a p-type layer, an i-type layer, and an n-type layer from a side of incidence of light. As a method of improving the conversion efficiency of the photoelectric conversion device, a method is known in which two or more types of photoelectric conversion unit are layered in the direction of light incidence. A first photoelectric conversion unit having a photoelectric conversion layer with a wider band gap is placed on the side of light incidence of the photoelectric conversion device, and then a second photoelectric conversion unit having a photoelectric conversion layer having a narrower band gap than the first photoelectric conversion unit is placed. With this configuration, photoelectric conversion is enabled for a wide wavelength range of the incident light, and the conversion efficiency of the overall device can be improved.

For example, as shown in FIG. 14, a photoelectric conversion device 100 is known in which an amorphous silicon photoelectric conversion unit (a-Si unit) 14 is set as a top cell and a microcrystalline photoelectric conversion unit (μc-Si unit) is set as a bottom cell to form a tandem structure, and a backside electrode layer 18 is formed thereon.

In such a tandem type photoelectric conversion device 100, a structure is known in which an intermediate layer 20 is provided between the s-Si unit 14 and the μc-Si unit 16 (see the Patent Literature 1). For the intermediate layer 20, zinc oxide (ZnO), silicon oxide (SiOx), or the like is used. Other materials, such as silicon oxide material, silicon carbon material, silicon nitride material, diamond like carbon, or the like, can also be used for the intermediate layer 20. The intermediate layer 20 is provided to have a lower refractive index of light than the a-Si unit 14 so as to allow light reflection toward the a-Si unit 14 between the a-Si unit 14 provided on the light incidence side and the intermediate layer 20.

### CITATION LIST

### Patent Literature

Patent Document 1: JP2004-260014A

### SUMMARY

### Technical Problem

However, when the light is reflected from the intermediate layer 20 to the a-Si unit 14 on the light incidence side, the refractive index is decreased from the a-Si unit 14, the transparent electrode layer 12, and the substrate 10 to air, so that the light reflected toward the a-Si unit 14 goes through the substrate 10, whereby the light is not fully used.

### Solution to Problem

According to one aspect of the present invention, there is provided a photoelectric conversion device including a p-type layer, an i-type layer, and an n-type silicon layer being layered sequentially, wherein a first intermediate layer formed between the p-type layer and the i-type layer and having a smaller refractive index than refractive indices of the p-type layer and the i-type layer, and a second intermediate layer formed between the n-type layer and the i-type layer and having a smaller refractive index than refractive indices of the i-type layer, are provided.

### Effect of Invention

According to the present invention, a utilization ratio of the photoelectric conversion device can be increased to improve photoelectric conversion efficiency.

### BRIEF DESCRIPTION OF DRAWINGS

FIG. 1 is a schematic cross section showing a configuration of a photoelectric conversion device according to a first embodiment of the present invention;

FIG. 2 is a graph showing the refractive index of the photoelectric conversion device according to the first embodiment;

FIG. 3 is a schematic cross section showing the configuration of a modified example of the photoelectric conversion device according to the first embodiment;

FIG. 4 is a schematic cross section showing the configuration of a modified example of the photoelectric conversion device according to the first embodiment;

FIG. 5 is a schematic cross section showing the configuration of a photoelectric conversion device according to a second embodiment of the present invention;

FIG. 6 is a graph showing the refractive index of the photoelectric conversion device according to the second embodiment;

FIG. 7 is a schematic cross section showing the configuration of a modified example of the photoelectric conversion device according to the second embodiment;

FIG. 8 is a schematic cross section showing the configuration of a photoelectric conversion device according to a third embodiment of the present invention;

FIG. 9 is a graph showing the refractive index of the photoelectric conversion device according to the third embodiment;

FIG. 10 is a schematic cross section showing the refractive index of a modified example of the photoelectric conversion device according to the third embodiment;

FIG. 11 is a schematic cross section showing the configuration of a photoelectric conversion device according to a fourth embodiment of the present invention;

FIG. 12 is a graph showing the refractive index of the photoelectric conversion device according to the fourth embodiment;

FIG. 13 is a schematic cross section showing the refractive index of a modified example of the photoelectric conversion device according to the fourth embodiment; and

FIG. 14 is a schematic cross section showing the configuration of a conventional photoelectric conversion device.

### DESCRIPTION OF EMBODIMENTS

### First Embodiment

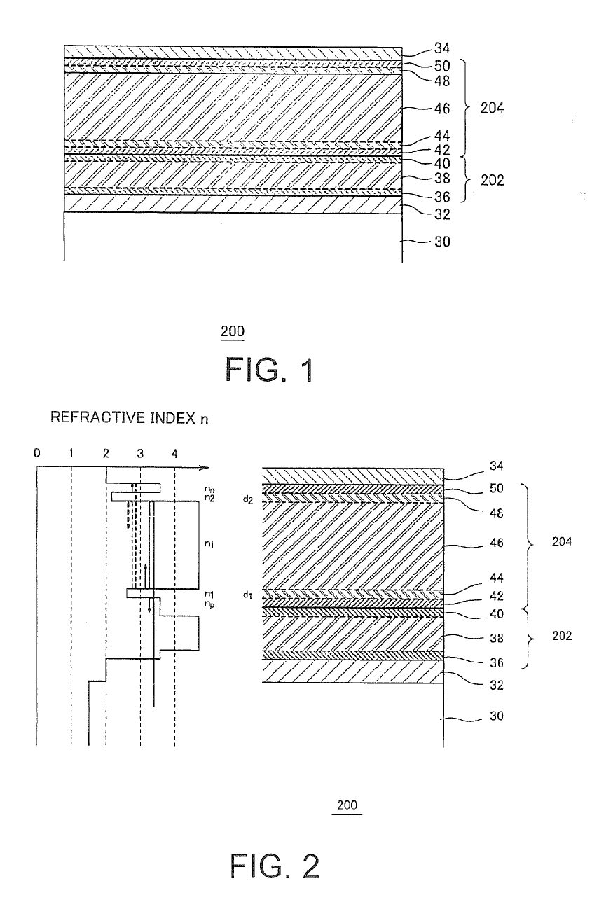

FIG. 1 is a cross sectional view showing a configuration of a photoelectric conversion device 200 according to a first embodiment of the present invention. The photoelectric conversion device 200 of the present embodiment has a structure in which a transparent insulating substrate 30 is set at a light incidence side, and a transparent conductive layer 32, an amorphous silicon photoelectric conversion unit (a-Si unit) 202 functioning as a top cell and having a wide band gap, a microcrystalline silicon photoelectric conversion unit (μc-Si unit) 204 functioning as a bottom cell and having a narrower band gap than the a-Si unit 202, and a backside electrode layer 34 are layered from the light incidence side.

The transparent insulating substrate 30 may be made of a material having light transmittance at least in a visible light wavelength region, and a glass substrate, a plastic substrate, or the like, may be used. The transparent conductive layer 32 is formed over the transparent insulating substrate 30. Preferably, the transparent conductive layer 32 may be made of at least one of, or a combination of, a plurality of transparent conductive oxides (TCO) in which tin (Sn), antimony (Sb), fluorine (F), aluminum (Al), or the like is doped into tin oxide (SnO₂), zinc oxide (ZnO), indium tin oxide (ITO), or the like. In particular, zinc oxide (ZnO) is preferable because it has a high light transmittance, a low resistivity, and a high plasma endurance characteristic. The transparent conductive layer 32 can be formed, for example, through sputtering, CVD, or the like. A thickness of the transparent conductive layer 32 is preferably set in a range of greater than or equal to 0.5 μm and less than or equal to 5 μm. In addition, it is preferable to provide unevenness having a light confinement effect on a surface of the transparent conductive layer 32.

Silicon-based thin films, that is, a p-type layer 36, an i-type layer 38, and an n-type layer 40 are sequentially layered over the transparent conductive layer 32 to form the a-Si unit 202. The a-Si unit 202 may be formed through plasma CVD in which mixture gas selected from silicon-containing gas such as silane (SiH₄), disilane (Si₂H₆), and dichlorosilane (SiH₂Cl₂), hydrocarbon gas such as methane (CH₄), p-type dopant-containing gas such as diborane (B₂H₆), n-type dopant containing gas such as phosphine (PH₃), and dilution gas such as hydrogen (H₂) is made into plasma and the unit is thus formed. Specific film formation conditions are shown in Table 1.

TABLE 1

| | | SUBSTRATE | GAS FLOW | REACTION | |
|---|---|---|---|---|---|
| | | TEMPERATURE | RATE | PRESSURE | RF POWER |
| | LAYER | (° C.) | (sccm) | (Pa) | (kW) |
| a-Si | p-TYPE | 180 | SiH₄: 75 | 80 | 56 |
| UNIT | LAYER | | CH₄: 150 | | (0.01 W/cm²) |
| 202 | 36 | | H₂: 750 | | |
| | | | B₂H₆: 2-23 | | |
| | i-TYPE | 180 | SiH₄: 600 | 100 | 60 |
| | LAYER | | H₂: 2000 | | (0.012 W/cm²) |
| | 38 | | | | |
| | n-TYPE | 180 | SiH₄: 20 | 200 | 600 |
| | LAYER | | H₂: 4000 | | (0.12 W/cm²) |
| | 40 | | PH₃: 10 | | |

For the plasma CVD, for example, RF plasma CVD of 13.56 MHz is preferably applied. The RF plasma CVD may be of a parallel plate-type. In general, the p-type layer 36, the i-type layer 38, and the n-type layer 40 are formed in different film formation chambers. The film formation chamber can be vacuumed using a vacuum pump, and an electrode for the RF plasma CVD is built into the film formation chamber. In addition, a transporting device of the transparent insulating substrate 30, a power supply and a matching device for the RF plasma CVD, pipes for supplying gas, etc. are provided.

The p-type layer 36 is formed on the transparent conductive layer 32. The p-type layer 36 is preferably a p-type amorphous silicon layer (p-type a-Si:H) or a p-type amorphous silicon carbide layer (p-type a-SiC:H), doped with a p-type dopant (such as boron) and having a thickness of greater than or equal to 10 nm and less than or equal to 100 nm. A film characteristic of the p-type layer 36 can be changed by adjusting the mixture ratio of silicon-containing gas, hydrocarbon gas, p-type dopant, and dilution gas, as well as pressure and plasma generating high-frequency power. For the i-type layer 38, a non-doped amorphous layer formed over the p-type layer 36 and having a thickness of greater than or equal to 50 nm and less than or equal to 500 nm is employed. The film characteristic of the i-type layer 38 can be changed by adjusting the mixture ratio of silicon-containing gas and dilution gas, as well as pressure and plasma generating high-frequency power. The i-type layer 38 functions as a power generating layer of the a-Si unit 202. For the n-type layer 40, an n-type amorphous silicon layer (n-type a-Si:H) or an n-type microcrystalline silicon layer (n-type μc-Si:H) formed over the i-type layer 38, doped with an n-type dopant (such as phosphorus), and having a thickness of greater than or equal to 10 nm and less than or equal to 100 nm is employed. The film characteristic of the n-type layer 40 can be changed by adjusting the mixture ratio of the silicon-containing gas, hydrocarbon gas, n-type dopant-containing gas, and dilution gas, as well as pressure and plasma generating high-frequency power.

Next, a p-type layer 42, a first intermediate layer 44, an i-type layer 46, a second intermediate layer 48, and an n-type layer 50 are sequentially layered in this order to form the μc-Si unit 204. The μc-Si unit 204 may be formed through plasma CVD in which mixture gas selected from silicon-containing gas such as silane (SiH₄), disilane (Si₂H₆), dichlorosilane (SiH₂Cl₂), hydrocarbon gas such as methane (CH₄), p-type dopant-containing gas such as diborane (B₂H₆), n-type dopant-containing gas such as phosphine (PH₃), carbon oxide gas such as carbon dioxide (CO₂), and dilution gas such as hydrogen (H₂) is made into plasma and the unit is thus formed. Specific film formation conditions are shown in FIG. 2.

TABLE 2

| | | SUBSTRATE | GAS FLOW | REACTION | | |
|---|---|---|---|---|---|---|
| | | TEMPERATURE | RATE | PRESSURE | | RF POWER |
| | LAYER | (° C.) | (sccm) | (Pa) | FREQUENCY | (kW) |
| a-Si | p-TYPE LAYER | 200 | SiH₄: 25 | 106 | RF | 250 |
| UNIT | 42 | | H₂: 5000 | | | (0.05 W/cm²⁾ |
| 204 | | | B₂H₆: 5 | | | |
| | FIRST | 180 | SiH₄: 20 | 200 | RF | 56 |
| | INTERMEDIATE | | CO₂: 40 | | | (0.15 W/cm₂) |
| | LAYER 44 | | H₂: 6000 | | | |
| | | | B₂H₆: 90 | | | |
| | i-TYPE LAYER | 180 | SiH₄: 300 | 9600-10000 | VHF | 2500 |
| | 46 | | H₂: 14000 | | (27 MHz) | (0.5 W/cm²) |
| | SECOND | 180 | SiH₄: 20 | 200 | RF | 56 |
| | INTERMEDIATE | | CO₂: 40 | | | (0.15 W/cm²) |
| | LAYER 48 | | H₂: 6000 | | | |
| | | | PH₃: 90 | | | |
| | n-TYPE LAYER | 200 | SiH₄: 25 | 133 | RF | 1500 |
| | 50 | | H₂: 5000 | | | (0.3 W/cm²) |
| | | | PH₃: 25 | | | |

Similar to the a-Si unit 202, for the plasma CVD, for example, RF plasma CVD of 13.56 MHz is preferably applied. In general, the p-type layer 42, the i-type layer 46 and the n-type layer 50 are formed in different film formation chambers. The first and second intermediate layers 44 and 48 may be formed in any film formation chamber of the p-type layer 36, the n-type layer 40, the p-type layer 42, or the n-type layer 50.

The p-type layer 42 is formed over the n-type layer 40 of the a-Si unit 202. Preferably, the p-type layer 42 may be a microcrystalline silicon layer, an amorphous silicon layer, or a combination thereof. The film characteristic of the p-type layer can be changed by adjusting the mixture ratio of silicon-containing gas, hydrocarbon gas, n-type dopant-containing gas, and dilution gas, as well as pressure and plasma generating high-frequency power.

The first intermediate layer 44 is formed on the p-type layer 40. The first intermediate layer 44 and the second intermediate layer 48 serve to confine light in the i-type layer 46 functioning as a power generating layer of the μc-Si unit 204. Preferably, the first intermediate layer 44 may be a silicon oxide-containing layer doped with a p-type dopant (boron). For example, the first intermediate layer 44 may be formed through plasma CVD using mixture gas of silicon-containing gas, p-type dopant-containing gas, and dilution gas such as carbon oxide gas such as carbon dioxide (CO₂). The film characteristic of the p-type layer 44 can be changed by adjusting additive gas species, mixture ratios of gas, pressure, and plasma generating high-frequency power.

The i-type layer 46 is formed on the first intermediate layer 44. The i-type layer 46 is a non-doped microcrystalline silicon film having a thickness of greater than or equal to 0.5 μm and less than or equal to 5 μm. The i-type layer 46 serves as a power generating layer of the μc-Si unit 204. Preferably, the i-type layer 46 has a layered structure in which a buffer layer is formed, followed by forming a main power generating layer on the buffer layer. The buffer layer is formed with a film forming condition which allows a higher crystallization ratio than the main power generating layer. Specifically, the buffer layer is formed with such a film forming condition as to provide a higher crystallization ratio of the buffer layer than the main power generating layer, when the buffer layer is formed on the glass substrate or the like as a single film. The film characteristic of the p-type layer 46 can be changed by adjusting the mixture ratio of silicon-containing gas and dilution gas, pressure, and plasma generating high-frequency power.

The second intermediate layer 48 is formed on the i-type layer 46. Preferably, the second intermediate layer 48 is a silicon oxide-containing layer doped with an n-type dopant (such as phosphorous). For example, it is preferable that the second intermediate layer 48 is formed through plasma CVD using mixture gas of silicon-containing gas, n-type dopant-containing gas, and dilution gas, mixed with carbon oxide gas such as carbon dioxide (CO₂). The film characteristic of the second intermediate layer 48 can be changed by adjusting additive gas species, mixture ratios of gas, pressure and plasma generating high-frequency power.

The n-type layer 50 is formed on the second intermediate layer 48. The n-type layer 50 is an n-type microcrystalline silicon layer (n-type μc-Si:H) doped with an n-type dopant (such as phosphorous) and having a thickness of greater than or equal to 5 nm and less than or equal to 50 nm. The film characteristic of the n-type layer 50 can be changed by adjusting the mixture ratio of silicon-containing gas, hydrocarbon gas, n-type dopant-containing gas and dilution gas, pressure, and plasma generating high-frequency power.

It is noted, however, that the μc-Si unit 204 of the present embodiment is not limited to this, and any unit may be used so long as the i-type microcrystalline silicon layer (i-type μc-Si:H) is used for the i-type layer 46 functioning as a power generation layer, and the first and second intermediate layers 44 and 48 are provided so as to sandwich the i-type layer 46. The first and second intermediate layers 44 and 48 will be described in more detail later.

The backside electrode layer 34 is formed on the μc-Si unit 204. Preferably, the backside electrode layer 34 has a layered structure of a reflective metal and a transparent conductive oxide (TCO). For the transparent conductive oxide (TCO), tin oxide (SnO₂), zinc oxide (ZnO), and indium tin oxide (Ito), or the like, or an impurity-doped material thereof is employed. For example, zinc oxide (ZnO) doped with aluminum (Al) as an impurity may be used. For the reflective metal, a metal such as silver (Ag) or aluminum (Al) is employed. The transparent conductive oxide (TCO) and the reflective metal may be formed, for example, through sputtering or a CVD method. Preferably, at least one of the transparent conductive oxide (TCO) and the reflective metal is provided with unevenness to improve the light confinement effect.

In addition, the backside electrode 34 may be covered by a protective film (not shown). The protective film may be made of a resin material such as EVA or polyimide, and adhered so as to cover the backside electrode layer 34 with a filler material made of a similar resin material. As such, it is possible to prevent, for example, intrusion of moisture to the power generating layer of the photoelectric conversion device 200.

It is noted that a YAG laser (with a basic wave of 1064 nm and second harmonic of 532 nm) may be used to separate and pattern the transparent conductive layer 32, the a-Si unit 202, the μc-Si unit 204, and the backside electrode layer 34 to provide a structure in which a plurality of cells are connected in series.

Next, the first and second intermediate layers 44 and 48 will be described. FIG. 2 shows the refractive index of each layer of the photoelectric conversion device 200 of the present embodiment. As shown in FIG. 2, the refractive index n₁ of the first intermediate layer 44 and the refractive index n₂ of the second intermediate layer 48 are made smaller than the refractive index nᵢ of the i-type layer 46 of the μc-Si unit 204 subjected to light confinement. Also, the refractive index n₁ of the first intermediate layer 44 is smaller than the refractive index nₚ of the adjacent p-type layer 42. It is noted that a difference of refractive indices (nᵢ−n₁) of the first intermediate layer 44 and the i-type layer 46 is larger than the difference of refractive indices (nₚ−n₁) of the first intermediate layer 44 and the p-type layer 42. On the other hand, the refractive index n₂ of the second intermediate layer 48 is made smaller than the refractive index nₙ of the adjacent n-type layer 50. It is noted that a difference of refractive indices (nᵢ−n₂) of the second intermediate layer 48 and the i-type layer 46 is larger than the difference of the refractive indices (nₙ−n₂) of the second intermediate layer 48 and the n-type layer 50.

Thus, as shown by an arrow (a solid line) of FIG. 2, the incident light that is transmitted through the interface between the p-type layer 42 and the first intermediate layer 44 and has entered the i-type layer 46 is reflected at the interface between the i-type layer 46 and the second intermediate layer 48, and returned to the i-type layer 46. Further, the light reflected at the interface between the i-type layer 46 and the second intermediate layer 48 is re-reflected at the interface between the i-type layer 46 and the first intermediate layer 44 due to the difference of respective refractive indices when the light reaches the interface, and returned to the i-type layer 46. Thus, the light confinement effect in the i-type layer 46 of the μc-Si unit 20 functioning as a bottom cell is obtained by the first and second intermediate layers 44 and 48.

In addition, as indicated by an arrow (a broken line) in FIG. 2, some of the light is transmitted through the interface between the i-type layer 46 and the second intermediate layer 48, but that light reaches the n-type layer 50 and the backside electrode layer 34 to be reflected due to the difference of refractive indices, and is returned to the i-type layer 46 through the n-type layer 50 and the second intermediate layer 48. Then, as described above, the light reflected from the backside electrode layer 34 is also confined in the i-type layer 46 by the first and second intermediate layers 44 and 48.

As such, a light utilization ratio in the i-type layer 46 of the μc-Si unit 204 functioning as a bottom cell can be improved.

It is noted that in general, because the refractive indices nₚ, n₁, and nₙ of the p-type layer 42, the i-type layer 46 and the n-type layer 50, respectively, are greater than 3.6, the refractive indices n₁, n₂ of the first and second intermediate layers 44, 48 are preferably equal to or less than 3.6. Also, it is preferable that the refractive indices n₁, n₂ of the first and second intermediate layers 44, 48 are set to be as small as possible, for example, about 2.1 so as to not deteriorate the film characteristic of the first and second intermediate layers 44, 48.

Here, it is preferable that the refractive index n₁ of the first intermediate layer 44 is set larger than the refractive index n₂ of the second intermediate layer 48. Because the refractive index nₚ of the p-type layer 42 and the refractive index nₙ of the n-type layer 44 are at almost the same level, a light introduction ratio into the i-type layer 46 can be higher at the interface between the p-type layer 42 and the first intermediate layer 44, than that at the interface between the n-type layer 50 and the second intermediate layer 48.

Also, it is preferable to set a film thickness d₁ of the first intermediate layer 44 to be equal to or less than a film thickness d₂ of the second intermediate layer 48. Thus, the refractive index at the interface between the first intermediate layer 44 and the i-type layer 46 is somewhat lower than the refractive index at the interface between the i-type layer 46 and the second intermediate layer 48, but as this leads to restriction in light absorption in the first intermediate layer 44 arranged on the side of light incidence from the transparent insulating substrate 30, the amount of light reaching the i-type layer 46 can be increased, and the power generation efficiency of the entire photoelectric conversion device 200 can be improved. On the other hand, the amount of light absorption in the second intermediate layer 48 is greater than the amount of light absorption in the first intermediate layer 44, but the light reflected from the backside electrode 34 to the second intermediate layer 48 is smaller than the incident light from the side of the transparent insulating substrate 30 to the first intermediate layer 44, so that the light confinement effect in the i-type layer 46 can be increased by raising the refractive index at the interface between the i-type layer 46 and the second intermediate layer 48, whereby the power generation efficiency of the entire photoelectric conversion device 200 can be improved.

More specifically, the film thicknesses d₁, d₂ of the first and second intermediate layers 44, 48, respectively, are preferably from equal to or more than 30 nm to equal to or less than 100 nm. In particular, the film thickness d₁ of the first intermediate layer 44 is preferably in a range from equal to or greater than 30 nm to equal to or less than 50 nm, and the film thickness d₂ of the second intermediate layer 48 is preferably equal to or greater than the film thickness d₁ of the first intermediate layer 44, and more preferably in a range from equal to or greater than 50 nm to equal to or less than 100 nm.

It is noted that the refractive indices n₁, n₂ of the first and second intermediate layers 44, 48 can be adjusted by controlling the mixture ratio of carbon oxide gas such as carbon dioxide (CO₂) relative to the mixture gas consisting of silicon-containing gas, dopant-containing gas, and dilution gas during the film formation. Specifically, the refractive indices n₁, n₂ can be lowered by increasing the mixture ratio of oxygen-containing gas such as carbon dioxide (CO₂). In addition, the refractive indices n₁, n₂ of the first and second intermediate layers 44, 48 can also be changed by adjusting the film formation conditions of the first and second intermediate layers 44, 48, such as pressure and plasma generating high frequency power through plasma CVD.

The refractive index of each layer can be known by carrying out component analysis through energy distribution type X-ray analysis (EDX) on cross sections of the photoelectric conversion device 200. In the component analysis by EDX, if an oxygen (O) content in a particular cross sectional region of interest is higher than that of other cross sectional regions, it can be determined that the cross sectional region of interest has a lower refractive index than other regions concerned. For example, if any layer having a higher oxygen (O) content than the i-type layer 46 is provided on either side of the i-type layer 46 of the μc-Si unit 204, that can be determined to be the configuration of the photoelectric conversion device 200 of the present embodiment. Similarly, the relationship between the refractive indices of the first and second intermediate layers 44, 48 and the p-type and n-type layers 42, 50 can also be determined.

The relationship of the refractive indices of each layer can also be determined similarly in other embodiments and modifications which will be described later.

It is noted that in the present embodiment, the silicon oxide-containing layer doped with impurities is applied as the first and second intermediate layer 44, 48, but it is not limited to this.

For example, the transparent conductive oxides (TCO) such as zinc oxide (ZnO) may be employed for the first and second intermediate layers 44, 48. In particular, it is preferable to use zinc oxide (ZnO) doped with magnesium (Mg). The transparent conductive oxide (TCO) may be formed, for example, by sputtering or CVD.

### Modified Example 1

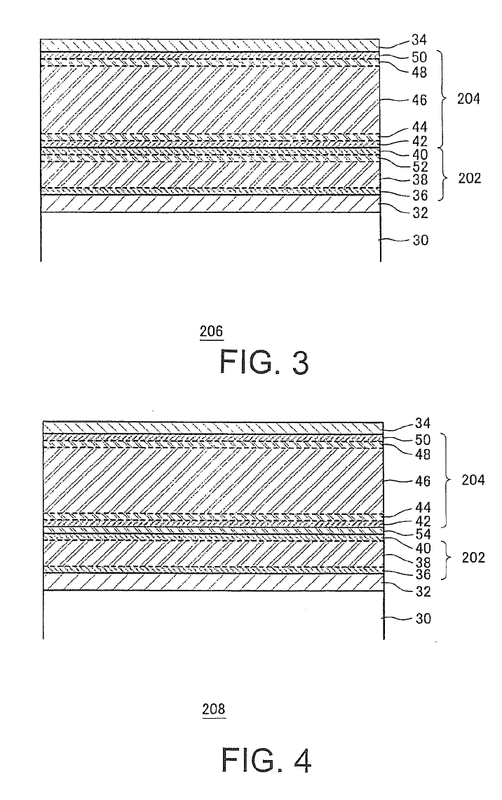

As a modified example of the photoelectric conversion device 200 according to the first embodiment, a third intermediate layer 52 may be provided as shown in a photoelectric conversion device 206 of FIG. 3. The third intermediate layer 52 is formed between the i-type layer 38 and the n-type layer 40 of the a-Si unit 202. Preferably, the third intermediate layer 52 is a silicon oxide-containing layer doped with an n-type dopant (phosphorous), similar to the second intermediate layer 48. For example, the third intermediate layer 52 is preferably formed through plasma CVD by using the mixture gas of silicon-containing gas, n-type dopant-containing gas, and dilution gas mixed with carbon oxide gas such as carbon dioxide (CO₂). The film characteristic of the third intermediate layer 52 can be changed by adjusting additive gas species, gas mixture ratios, pressure, and plasma generating high frequency power.

Preferably, a refractive index n₃ of the third intermediate layer 52 is set smaller than a refractive index nₐᵢ of the i-type layer 38 and a refractive index nₐₙ of the n-type layer 40. The refractive index n₃ of the third intermediate layer 52 can be adjusted by controlling the mixture ratio of carbon oxide gas such as carbon dioxide (CO₂) relative to the mixture gas consisting of silicon-containing gas, dopant-containing gas, and dilution gas during film formation.

As such, by additionally providing the third intermediate layer 52, the light reaching the interface between the i-type layer 38 and the third intermediate layer 52 of the a-Si unit 202 is reflected due to the difference of refractive indices, and returned to the i-type layer 38. As a result, the light utilization ratio in the i-type layer 38 can be improved, and an advantage such as an ability to reduce the film thickness of the i-type layer 38 functioning as the power generation layer of the a-Si unit 202 can be obtained.

It is noted that the first intermediate layer 44 may not be provided, and the third intermediate layer 52 may be provided instead. In this case, the light confinement effect can be obtained between the third intermediate layer 52 and the second intermediate layer 48. However, because the confined light is absorbed in the n-type layer 40 and the p-type layer 42, it is preferable to provide the first intermediate layer 44.

### Modified Example 2

As a modified example of the photoelectric conversion device 200 according to the first embodiment, a third intermediate layer 54 may be provided, as shown in a photoelectric conversion device 208 of FIG. 4. The third intermediate layer 54 is provided between the n-type layer 40 of the a-Si unit 202 and the p-type layer 42 of the μc-Si unit 204. Preferably, the third intermediate layer 54 is a silicon oxide-containing layer doped with a p-type dopant (such as boron) or an n-type dopant (such as phosphorous), similar to the first or second intermediate layer 44, 48. For example, the third intermediate layer 54 is preferably formed through plasma CVD by using the mixture gas of silicon-containing gas, dopant-containing gas, and dilution gas mixed with carbon oxide gas such as carbon dioxide (CO₂). The film characteristic of the third intermediate layer 54 can be changed by adjusting additive gas species, gas mixture ratios, pressure, and plasma generating high frequency power.

Preferably, a refractive index n₄ of the third intermediate layer 54 is set smaller than the refractive index nₐₙ of the n-type layer 40 and the refractive index nₚ of the p-type layer 42. The refractive index n₄ of the third intermediate layer 54 can be adjusted by controlling the mixture ratio of carbon oxide gas such as carbon dioxide (CO₂) relative to the mixture gas of silicon-containing gas, dopant-containing gas, and dilution gas during film formation.

As such, by additionally providing the third intermediate layer 54, the light reaching the interface between the n-type layer 40 of the a-Si unit 202 and the p-type layer 42 of the μc-Si unit 204 is reflected due to the difference of refractive indices and returned to the i-type layer 38 through the n-type layer 40. As a result, the light utilization ratio in the i-type layer 38 can be improved, and an advantage such as an ability to reduce the film thickness of the i-type layer 38 functioning as the power generation layer of the a-Si unit 202 can be obtained.

It is noted that the first intermediate layer 44 may not be provided, and the third intermediate layer 54 may be provided instead. In this case, the light confinement effect can be obtained between the third intermediate layer 54 and the second intermediate layer 48 of the i-type layer 46 of the μc-Si unit 204. However, because the confined light is absorbed in the p-type layer 42, it is preferable to provide the first intermediate layer 44.

### Second Embodiment

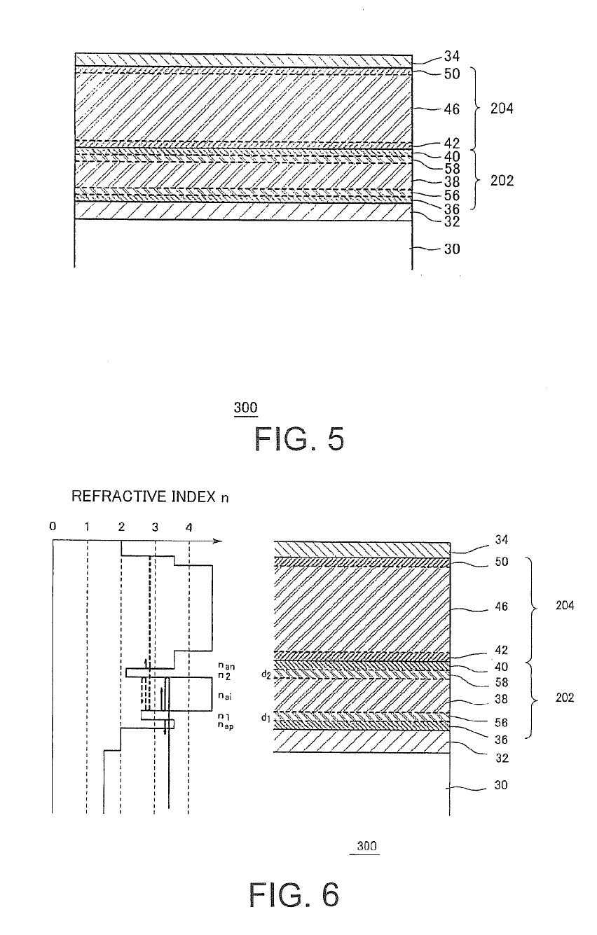

FIG. 5 is a cross sectional view showing a configuration of a photoelectric conversion device 300 according to a second embodiment. In the photoelectric conversion device 300 of the present embodiment, the first intermediate layer 44 and the second intermediate layer 48 of the μc-Si unit 204 are not provided as in the photoelectric conversion device 200 of the first embodiment, and a first intermediate layer 56 and a second intermediate layer 58 are provided in the a-Si unit 202 instead. The film formation method of each layer is similar to that in the first embodiment, and therefore it will not be described again.

FIG. 6 shows the refractive index of each layer of the photoelectric conversion device 300 of the present embodiment. As shown in FIG. 6, the refractive index n₁ of the first intermediate layer 56 and the refractive index n₂ of the second intermediate layer 58 are made smaller than the refractive index nₐᵢ of the i-type layer 38 of the μc-Si unit 202 subjected to light confinement. Also, the refractive index n₂ of the first intermediate layer 56 is smaller than the refractive index nₐₚ of the adjacent p-type layer 36. It is noted that a difference of the refractive indices (nₐᵢ−n₁) of the first intermediate layer 56 and the i-type layer 38 is larger than the difference of refractive indices (nₐₚ−n₁) of the first intermediate layer 56 and the p-type layer 36. On the other hand, the refractive index n₂ of the second intermediate layer 58 is made smaller than the refractive index nₐₙ of the adjacent n-type layer 40. It is noted that a difference of refractive indices (nₐᵢ−n₂) of the second intermediate layer 58 and the i-type layer 38 is larger than the difference of the refractive indices (nₐₙ−n₂) of the second intermediate layer 58 and the n-type layer 40.

Thus, as shown by an arrow (a solid line) in FIG. 6, the incident light that is transmitted through the interface between the p-type layer 36 and the first intermediate layer 56 and has entered the i-type layer 38 is reflected at the interface between the i-type layer 38 and the second intermediate layer 58, and returned to the i-type layer 38. Further, the light reflected at the interface between the i-type layer 38 and the second intermediate layer 58 is re-reflected at the interface between the i-type layer 38 and the first intermediate layer 56 due to the difference of respective refractive indices when the light reaches the interface, and returned to the i-type layer 38. Thus, the light confinement effect in the i-type layer 38 of the μc-Si unit 202 functioning as a top cell is obtained by the first and second intermediate layers 56 and 58.

In addition, as indicated by an arrow (a broken line) in FIG. 6, some of the light is transmitted through the interface between the i-type layer 38 and the second intermediate layer 58, but when that light is reflected at the n-type layer 50 and the backside electrode layer 34 and returned to the i-type layer 38, the light is confined in the i-type layer 38 by the first and second intermediate layers 56 and 58.

As such, a light utilization ratio in the i-type layer 38 of the μc-Si unit 202 functioning as top cell can be improved.

It is noted that because the refractive indices nₐₚ, nₐᵢ, and nₐₙ of the p-type layer 36, the i-type layer 38 and the n-type layer 40, respectively, are generally greater than 3.6, the refractive indices n₁, n₂ of the first and second intermediate layers 56, 58 are preferably equal to or less than 3.6. Also, it is preferable that the refractive indices n₁, n₂ of the first and second intermediate layers 56, 58 are as small as possible, for example, of about 2.1.

Here, it is preferable that the refractive index n₁ of the first intermediate layer 56 is set larger than the refractive index n₂ of the second intermediate layer 58. Because the refractive index nₐₚ of the p-type layer 36 and the refractive index nₐₙ of the n-type layer 40 are at almost the same level, a light introduction ratio into the i-type layer 38 can be improved at the interface between the p-type layer 36 and the first intermediate layer 56 compared to at the interface between the n-type layer 40 and the second intermediate layer 58.

Also, it is preferable to set a film thickness d₁ of the first intermediate layer 56 to be equal to or less than a film thickness d₂ of the second intermediate layer 58. Thus, the refractive index at the interface between the first intermediate layer 56 and the i-type layer 38 is somewhat lower than the refractive index at the interface between the i-type layer 38 and the second intermediate layer 58, but as this leads to restriction in light absorption in the first intermediate layer 56 arranged on the side of light incidence from the transparent insulating substrate 30, the amount of light reaching the i-type layer 38 can be increased, and the power generation efficiency of the entire photoelectric conversion device 300 can be improved. On the other hand, the amount of light absorption in the second intermediate layer 58 is greater than the amount of light absorption in the first intermediate layer 56, but the light reflected from the backside electrode 34 to the second intermediate layer 58 is smaller than the incident light from the side of the transparent insulating substrate 30 to the first intermediate layer 56, so that the light confinement effect in the i-type layer 46 can be increased by raising the refractive index at the interface between the i-type layer 38 and the second intermediate layer 58, whereby the power generation efficiency of the entire photoelectric conversion device 300 can be improved.

More specifically, the film thicknesses d₁, d₂ of the first and second intermediate layers 56, 58, respectively, are preferably from equal to or more than 30 nm to equal to or less than 100 nm. In particular, the film thickness d₁ of the first intermediate layer 56 is preferably in a range from equal to or greater than 30 nm to equal to or less than 50 nm, and the film thickness d₂ of the second intermediate layer 58 is preferably in a range from equal to or greater than the film thickness d₁ of the first intermediate layer 56, and more preferably in a range from equal to or greater than 50 nm to equal to or less than 100 nm.

### Modified Example 3

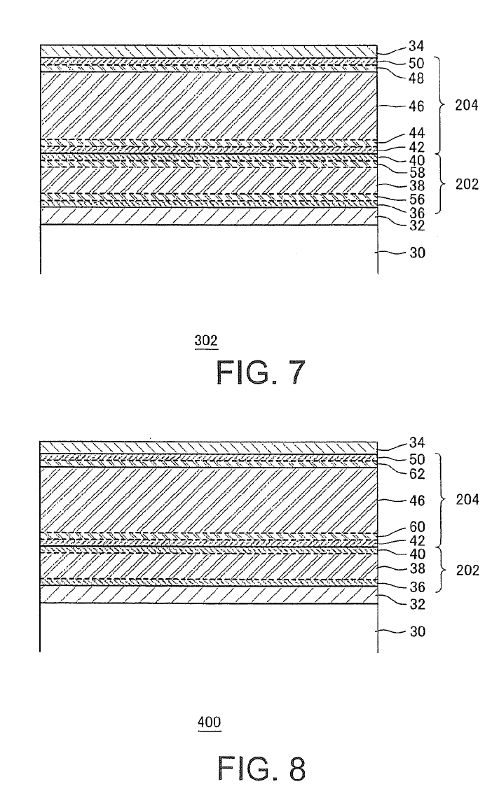

The photoelectric conversion device 200 of the first embodiment may be combined with the structure of the photoelectric conversion system 300. Specifically, as shown in FIG. 7, a photoelectric conversion device 302 may include the first and second intermediate layers 56, 58 in the a-Si unit 202, and the first and second intermediate layers 44, 48 in the μSi-unit 204.

As a result, the light confinement effect is obtained in both i-type layers 38, 46 functioning as power generation layers of the a-Si unit 202 and the μc-Si unit 204, respectively, whereby the power generation efficiency of the photoelectric conversion device 302 can be improved.

### Third Embodiment

In the above-described first and second embodiments, as well as modified examples thereof, the refractive indices of respective intermediate layers are set to be unchanged in the direction of film thickness. In a third embodiment, the refractive index of the intermediate layer is changed in the direction of film thickness.

FIG. 8 is a cross sectional view showing a configuration of a photoelectric conversion device 400 according to the third embodiment. The photoelectric conversion device 400 of the present embodiment includes a first intermediate layer 60 and a second intermediate layer 62 in the μc-Si unit 204, instead of the first and second intermediate layers 44, 48 in the photoelectric conversion device 200 of the first embodiment.

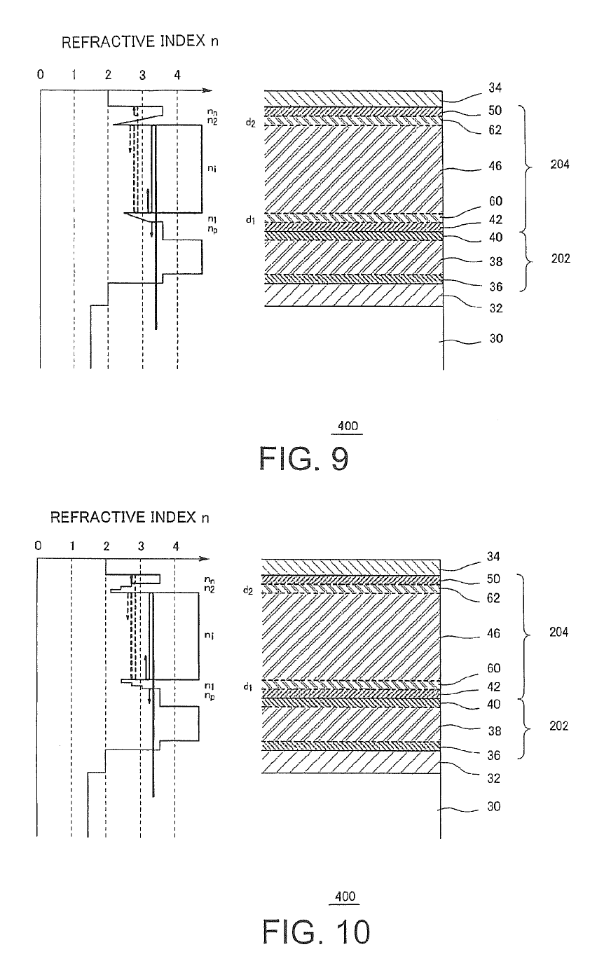

Here, the first and second intermediate layers 60, 62 are formed so that the refractive indices n₁, n₂ thereof change in the direction of film thickness. In the first intermediate layer 60, as shown in FIG. 9, the refractive index n₁ is gradually increasing from the side of the i-type layer 46 to the side of the p-type layer 42. As such, by changing the refractive index n₁ in an inclined manner, the difference of refractive indices (nₚ−n₁) at the interface between the p-type layer 42 and the first intermediate layer 60 for the incident light that has entered from the side of the p-type layer 42 becomes yet smaller than the difference of refractive indices (nᵢ−n₁) at the interface between the i-type layer 46 and the first intermediate layer 60, whereby light transmittance can be improved. On the other hand, when the incident light that has once entered the i-type layer 46 is reflected at any location such as between the n-type layer 50 and the backside electrode layer 34 and reaches the interface between the i-type layer 46 and the first intermediate layer 60, the reflectance of light toward the i-type layer 46 can be increased by the difference of refractive indices (nᵢ−n₁) at the interface between the i-type layer 46 and the first intermediate layer 60.

Preferably, the refractive index n₁ of the first intermediate layer 60 at the interface of the p-type layer 42 is set to be approximately equal to the refractive index nₚ of the p-type layer 42. Specifically, because the refractive index nₚ of the p-type layer 42 is about 3.6, it is preferable to set the refractive index n₁ of the first intermediate layer 60 to about 3.6 at the interface of the p-type layer 42. It is also preferable that the refractive index n₁ of the first intermediate layer 60 is set to be as small as possible so as to not deteriorate the film characteristic at the interface of the i-type layer 46. Specifically, it is preferable that the refractive index n₁ of the first intermediate layer 60 at the interface of the i-type layer 46 is set to about 2.1.

Also, as shown in FIG. 9, the second intermediate layer 62 is formed so that the refractive index n₂ is gradually increasing from the side of the i-type layer 46 to the n-type layer 50. As such, by changing the refractive index n₂ in an inclined manner, the difference of refractive indices (nₙ−n₂) at the interface between the n-type layer 50 and the second intermediate layer 62 becomes smaller than the difference of indices (nᵢ−n₂) at the interface between the i-type layer 46 and the second intermediate layer 62 for the incident light that is reflected from the backside electrode layer 34 or the like and has entered from the side of the n-type layer 50, whereby light transmittance can be improved. On the other hand, when the incident light that has once entered the i-type layer 46 reaches the interface between the i-type layer 46 and the second intermediate layer 62, the reflectance of light toward the i-type layer 46 can be increased by the difference of refractive indices (nᵢ−n₂) at the interface between the i-type layer 46 and the second intermediate layer 62.

Preferably, the refractive index n₂ of the second intermediate layer 62 is set to be approximately equal to the refractive index nₙ of the n-type layer 50 at the interface of the n-type layer 50. In particular, because the refractive index nₙ of the n-type layer 50 is about 3.6, the refractive index n₂ of the second intermediate layer 62 at the interface of the n-type layer 50 is preferably set to about 3.6. It is also preferable that the refractive index n₂ of the second intermediate layer 62 is set to be as small as possible so as to not deteriorate the film characteristic at the interface of the i-type layer 46. In particular, the refractive index n₂ of the second intermediate layer 62 at the interface of the i-type layer 46 is preferably set to about 2.1.

It is also preferable that the film thickness d₁ of the first intermediate layer 60 is set to be equal to or smaller than the film thickness d₂ of the second intermediate layer 62. Thus, the refractive index at the interface between the first intermediate layer 60 and the i-type layer 46 is somewhat lower than the refractive index at the interface between the i-type layer 46 and the second intermediate layer 62, but as this leads to restriction in light absorption in the first intermediate layer 60 arranged on the side of light incidence from the transparent insulating substrate 30, the amount of light reaching the i-type layer 46 can be increased, and the power generation efficiency of the entire photoelectric conversion device 400 can be improved. On the other hand, the amount of light absorption in the second intermediate layer 62 is larger than the amount of light absorption in the first intermediate layer 60, but as the light reflected from the backside electrode layer 34 and entering the second intermediate layer 62 is smaller than the incident light entering the first intermediate layer 60 from the side of the transparent insulating substrate 30, the light confinement effect in the i-type layer 46 is increased by raising the refractive index at the interface between the i-type layer 46 and the second intermediate layer 62, and the power generation efficiency of the entire photoelectric conversion device 400 can be improved.

Specifically, as in the first embodiment, it is preferable that the film thicknesses d₁, d₂ of the first and second intermediate layers 60, 62, respectively, are set to be equal to or greater than 30 nm and equal to or less than 100 nm. In particular, the film thickness d₁ of the first intermediate layer 60 is preferably set to be within a range from equal to or greater than 30 nm and equal to or less than 50 nm, and the film thickness d₂ of the second intermediate layer 62 is preferably set to be within a range from equal to or greater than 50 nm to equal to or smaller than 100 nm.

It is noted that the refractive indices n₁, n₂ of the first and second intermediate layers 60, 62, respectively, are not limited to be inclined sequentially in the direction of film thickness, and may be changed stepwise as shown in FIG. 10.

In order to change the refractive indices n₁, n₂ of the first and second intermediate layers 60, 62, respectively, in the direction of film thickness, the mixture ratio of oxygen-containing gas such as carbon dioxide (CO₂) relative to the mixture gas consisting of silicon-containing gas, dopant-containing gas, and dilution gas may be changed. Specifically, the mixture ratio of oxygen-containing gas such as carbon dioxide (CO₂) may be adjusted to be higher so that the refractive indices n₁, n₂ are decreased. Also, the refractive indices n₁, n₂ of the first and second intermediate layers 60, 62 can be changed by adjusting the film formation conditions such as pressure and plasma generating high frequency power during film formation of the first and second intermediate layers 60, 62 through plasma CVD.

It is noted that similar effects can be obtained even when at least one of the first and second intermediate layers 60, 62 is provided. Also, the first and second intermediate layers 60, 62 may be provided instead of the first and second intermediate layers 56, 58 of the a-Si unit 202 as in the second embodiment. Further, the first and second intermediate layers 60, 62 may be provided instead of the first and second intermediate layers 44, 48, or the first and second intermediate layers 56, 58 of the modified examples 1-3.

In addition, as in the first embodiment, the transparent conductive oxide (TCO) such as zinc oxide (ZnO) is employed for the first and second intermediate layers 60, 62. In particular, it is preferable to use zinc oxide (ZnO) doped with magnesium (Mg). In this case, the refractive indices n₁, n₂ of the first and second intermediate layers 60, 62 may also be changed in an inclined manner or stepwise by adjusting the film formation conditions during film formation.

### Fourth Embodiment

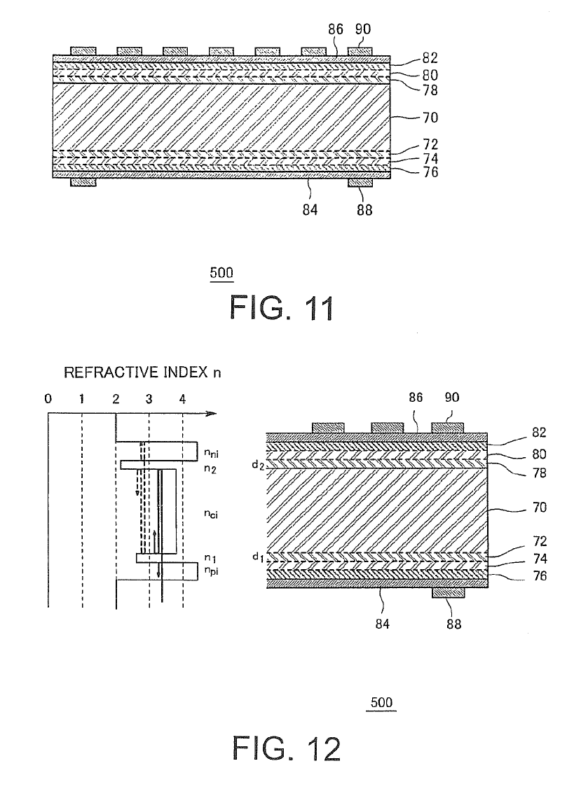

The present invention is applicable to a crystalline photoelectric conversion device. FIG. 11 is a schematic cross sectional view showing a structure of a photoelectric conversion device 500 having a single crystal silicon layer 70.

The photoelectric conversion device 500 has a structure in which a first intermediate layer 72, an intrinsic semiconductor layer 74, and a conductive type semiconductor layer 76 are sequentially layered on the surface (a first surface) of a single crystal silicon layer 70, and a second intermediate layer 78, an intrinsic semiconductor layer 80, and a conductive-type semiconductor layer 82 are sequentially layered on a backside (a second surface) of the single crystal silicon layer 70.

Preferably, the single crystal silicon layer 70 is made of an n-type single crystal silicon (resistivity=about 0.5-4 Ωcm). For example, the single crystal silicon layer 70 is preferably a square-shaped layer with a side of 100 mm and having a thickness of about 100-500 μm.

The first intermediate layer 72 is formed on the surface (the first surface) of the single crystal silicon layer 70. The first intermediate layer 72 can be formed in the same manner as the first intermediate layer 44 of the first embodiment. Over the first intermediate layer 72, the intrinsic semiconductor layer 74 (film thickness: about 50-200 Å) which is a non-doped amorphous silicon layer, and the conductive type semiconductor layer 76 (film thickness: about 50-150 Å) which is a p-type amorphous silicon layer doped with a p-type dopant, are formed through plasma CVD. It is noted that the intrinsic semiconductor layer 74 and the conductive type semiconductor layer 76 are made of amorphous silicon, but microcrystalline silicon may be employed instead.

The second intermediate layer 78 is formed on the backside (a second surface) of the single crystal silicon layer 70. The second intermediate layer 78 can be formed in the same manner as the second intermediate layer 48 of the first embodiment. Over the second intermediate layer 78, the intrinsic semiconductor layer 80 (film thickness: about 50-200 Å) which is a non-doped amorphous silicon layer, and the conductive type semiconductor layer 82 (film thickness: about 100-500 Å) which is an n-type amorphous silicon layer doped with an n-type dopant are formed through plasma CVD. It is noted that the intrinsic semiconductor layer 80 and the conductive type semiconductor layer 82 are made of amorphous silicon, but microcrystalline silicon may be employed instead.

Transparent conductive layers 84, 86 each having approximately the same area as the conductive type semiconductor layers 76, 82 are formed on these semiconductor layers. Further, collective electrodes 88, 90 made of a material such as silver paste are formed on the transparent conductive layers 84, 86. It is noted that the photoelectric conversion device 500 also has the transparent conductive layer 86 applied on the backside (the second surface), which contributes to power generation by incident light even when the light enters the backside.

FIG. 12 shows refractive indices of each layer of the photoelectric conversion device 500. As shown in FIG. 12, the refractive indices n₁, n₂ of the first and second intermediate layers 72, 78 are set to be smaller than the refractive index n_{ci} of the single crystal silicon layer 70 subjected to light confinement. Also, the refractive index n₁ of the first intermediate layer 72 is set to be smaller than the refractive index nₚᵢ of the adjacent intrinsic semiconductor layer 74 and the conductive type semiconductor layer 76. It is noted that the difference of refractive indices (n_{ci}−n₁) between the first intermediate layer 72 and the single crystal silicon layer 70 is set to be smaller than the difference of refractive indices (nₚᵢ−n₁) between the first intermediate layer 72 and the intrinsic semiconductor layer 74 and the conductive type semiconductor layer 76. Also, the refractive index n₂ of the second intermediate layer 78 is set to be smaller than the refractive index nₙᵢ of the adjacent intrinsic semiconductor layer 80 and the conductive type semiconductor layer 82. It is noted that the difference of refractive indices (n_{ci}−n₂) between the second intermediate layer 78 and the single crystal silicon layer 70 are set to be smaller than the difference of refractive indices (nₙᵢ−n₂) between the second intermediate layer 78 and the intrinsic conductive layer 80 and the conductive type semiconductor layer 82.

As such, as indicated by an arrow (a solid line) in FIG. 12, the incident light transmitted through the interface between the intrinsic semiconductor layer 74 and the first intermediate layer 72 and entering the single crystal silicon layer 70 is reflected at the interface between the single crystal silicon layer 70 and the second intermediate layer 78 due to the difference of refractive indices, and returned to the single crystal silicon layer 70. Further, the light reflected at the interface between the single crystal silicon layer 70 and the second intermediate layer 78 is re-reflected upon reaching the interface between the single crystal silicon layer 70 and the first intermediate layer 72 due to the difference of refractive indices, and returned to the single crystal silicon layer 70. Also, as indicated by an arrow (a broken line) in FIG. 12, the incident light transmitted through the interface between the intrinsic semiconductor layer 80 and the second intermediate layer 78 and entering the single crystal silicon layer 70 is reflected at the interface between the single crystal silicon layer 70 and the first intermediate layer 72 due to the difference of refractive indices, and returned to the single crystal layer 70. Further, upon reaching the interface between the single crystal silicon layer 70 and the second intermediate layer 78, the light is re-reflected due to the difference of refractive indices and returned to the single crystal silicon layer 70. As such, the light confinement effect in the single crystal silicon layer 70 can be obtained by the first and second intermediate layers 72, 78.

Further, it is preferable that the refractive index n₁ of the first intermediate layer 72 is set to be greater than the refractive index n₂ of the second intermediate layer 78. Because the refractive index nₚᵢ of the intrinsic semiconductor layer 74 and the conductive type semiconductor layer 76 is approximately at the same level as the refractive index nₙᵢ of the intrinsic semiconductor layer 80 and the conductive type semiconductor layer 82, the light introduction ratio into the single crystal silicon layer 70 can be higher at the interface between the intrinsic semiconductor layer 74 and the first intermediate layer 72, than at the interface between the intrinsic semiconductor layer 80 and the second intermediate layer 78.

Also, it is preferable to set the film thickness d₁ of the first intermediate layer 72 to be equal to or less than the film thickness d₂ of the second intermediate layer 78. Thus, the refractive index at the interface between the first intermediate layer 72 and the single crystal silicon layer 70 is somewhat decreased compared to the refractive index at the interface between the single crystal silicon layer 70 and the second intermediate layer 78, but as this leads to restriction in light absorption in the first intermediate layer 72 arranged on the side of major light incidence, the amount of light reaching the single crystal silicon layer 70 can be increased, and the power generation efficiency of the entire photoelectric conversion device 500 can be improved. On the other hand, the amount of light absorption in the second intermediate layer 78 is larger than that in the first intermediate layer 72, but the amount of light transmitted through the second intermediate layer 78 to reach the single crystal silicon layer 70 is smaller than the amount of light transmitted through the first intermediate layer 72 to reach the single crystal silicon layer 70, the light confinement effect in the single crystal silicon layer 70 can be improved by raising the refractive index at the interface between the single crystal silicon layer 70 and the second intermediate layer 78, and the power generation efficiency of the entire photoelectric conversion device 500 can be improved.

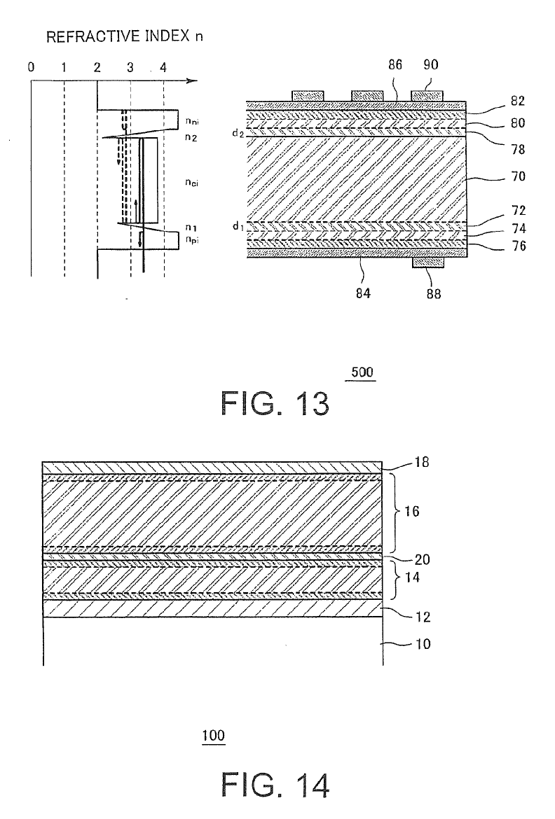

Also, as in the third embodiment, it is preferable that at least one of the refractive index n₁ of the first intermediate layer 72 and the refractive index n₂ of the second intermediate layer 78 is changed in an inclined manner or stepwise in the direction of film thickness. As shown in FIG. 13, the first intermediate layer 72 is formed so that the refractive index n₁ is gradually increased from the side of the single silicon layer 70 to the side of the intrinsic semiconductor layer 74. Also, the second intermediate layer 78 is formed so that the refractive index n₂ is gradually increased from the side of the single crystal silicon layer 70 to the side of the intrinsic semiconductor layer 80, as shown in FIG. 13.

It is preferable that the refractive index n₁ of the first intermediate layer 72 is set to be approximately the same as the refractive index nₚᵢ of the intrinsic semiconductor layer 74 at the interface of the intrinsic semiconductor layer 74. It is preferable that the refractive index n₂ of the second intermediate layer 78 is set to be approximately the same as the refractive index nₙᵢ of the intrinsic semiconductor layer 80 at the interface of the intrinsic semiconductor layer 80. Also, the refractive indices n₁, n₂ of the first and second intermediate layers 72, 78 are preferably set to be as small as possible so as to not deteriorate the film characteristic of the interface with the single crystal silicon layer 70.

As such, by changing at least either one of the refractive indices n₁, n₂ of the first and second intermediate layers 72, 78 in an inclined manner or stepwise in the direction of film thickness, the light confinement effect in the single crystal silicon layer 70 can be improved.

It is noted that the effect of improving the power generation efficiency of the photoelectric conversion device can be obtained by providing at least one of the first and second intermediate layers 72, 78. Also, in the photoelectric conversion device in which two or more single crystal silicon layers functioning as power generation layers 70 are stacked, the light confinement effect can be obtain by providing the first and second intermediate layers 72, 78 for each single crystal silicon layer 70.

### PARTS LIST

10: Substrate
12: Transparent Conductive Layer
14: Amorphous Silicon Photoelectric Conversion Unit (a-Si unit)
16: Microcrystalline Silicon Photoelectric Conversion Unit (μc-Si unit)
20: Intermediate Layer
30: Transparent Insulating Substrate
32: Transparent Conductive Layer
34: Backside Electrode Layer
36: p-type Layer (a-Si)
38: i-type Layer (a-Si)
40: n-type Layer (a-Si)
42: p-type Layer (μc-Si)
44, 56, 60, 72: First Intermediate Layer
48, 58, 62, 78: Second Intermediate Layer
50: n-type Layer (μc-Si)
52, 54: Third Intermediate Layer
70: Single Crystal Silicon Layer
74: Intrinsic Semiconductor Layer
76: Conductive-type Semiconductor Layer
80: Intrinsic Semiconductor Layer
82: Conductive-type Semiconductor Layer
84, 86: Transparent Conductive Layer
88, 90: Collective Electrode
100, 200, 206, 208, 300, 302, 400, 500: Photoelectric Conversion Unit
202: Amorphous Silicon Photoelectric Conversion Unit (a-Si unit)
204: Microcrystalline Silicon Photoelectric Conversion Unit (μc-Si Unit)

1. A photoelectric conversion device formed by layering a p-type layer, an i-type layer, and an n-type layer, comprising:
a first intermediate layer disposed between said p-type layer and said i-type layer and having a refractive index smaller than refractive indices of said p-type layer and said i-type layer; and
a second intermediate layer disposed between said n-type layer and said i-type layer and having a refractive index smaller than refractive indices of said n-type layer and said i-type layer, wherein
said first intermediate layer is arranged closer to a light incidence surface than said second intermediate layer and has a film thickness equal to or less than a film thickness of said second intermediate layer.

2. The photoelectric conversion device according to claim 1, wherein
at least one of said first intermediate layer and said second intermediate layer is arranged in contact with said i-type layer.

3. The photoelectric conversion device according to claim 1, wherein
said first intermediate layer has a refractive index greater than a refractive index of said second intermediate layer.

4. The photoelectric conversion device according to claim 2, wherein
said first intermediate layer has a refractive index greater than a refractive index of said second intermediate layer.
